(19) United States
(12) Patent Application Publication
(10) Pub. No.: US 2023/0065179 A1
(43) Pub. Date: Mar. 2, 2023

(54) METHOD FOR PRODUCING A MICROELECTRONIC DEVICE

(71) Applicant: Robert Bosch GmbH, Stuttgart (DE)

(72) Inventors: Jochen Tomaschko, Gaeufelden (DE); Daniel Monteiro Diniz Reis, Esslingen Am Neckar (DE); Frank Schatz, Kornwestheim (DE); Hans Artmann, Boeblingen-Dagersheim (DE); Rainer Straub, Ammerbuch (DE); Timo Schary, Aichtal-Neuenhaus (DE)

(21) Appl. No.: 17/794,459

(22) PCT Filed: Mar. 25, 2021
(86) PCT No.: PCT/EP2021/057683

§ 371 Date: Jul. 21, 2022

(30) Foreign Application Priority Data
Apr. 20, 2020 (DE) 10 2020 204 961.0

(51) Int. Cl. B81C 3/00; B81B 7/02; H01L 27/20

(52) U.S. Cl. CPC B81C 3/008; B81B 7/02; H01L 27/20; B81B 2201/038; B81C 2201/013; B81C 2201/018; B81C 2201/0154

(57) ABSTRACT

A method for producing a microelectronic device, in particular a MEMS chip device, comprising at least one carrier substrate. At least one electrodynamic actuator made of a metal conductor formed at least largely of copper is applied to the carrier substrate in at least one method step. At least one piezoelectric actuator is applied to the carrier substrate in at least one further method step.

### BACKGROUND INFORMATION

A method for producing a microelectronic device, in particular a MEMS chip device, is described in the related art, comprising at least one carrier substrate, wherein at least one electrodynamic actuator made of a metal conductor formed at least largely of copper is applied to the carrier substrate in at least one method step.

### SUMMARY

The present invention proceeds from a method for producing a microelectronic device, in particular a MEMS chip device, comprising at least one carrier substrate, wherein at least one electrodynamic actuator made of a metal conductor formed at least largely of copper is applied to the carrier substrate in at least one method step.

In accordance with an example embodiment of the present invention, it is provided that at least one piezoelectric actuator is applied to the carrier substrate in at least one further method step.

Preferably, the microelectronic device is designed as a MEMS chip device, in particular an automotive-electronics and/or consumer-electronics MEMS chip device, preferably comprising copper conducting tracks, in particular comprising low-resistance copper conducting tracks, in particular having a specific resistance of between 0.010 and 0.020 μOhm·m. For example, the microelectronic device is designed as a MEMS resonator device, in particular as a micromirror, preferably a biaxial micromirror. For example, the microelectronic device is designed as a sensor, in particular an angular rate sensor. Preferably, the micromirror has a resonant axis and/or a quasi-static axis. Preferably, in at least one method step, a silicon wafer is used as the at least one carrier substrate. In particular, the at least one carrier substrate is designed as a silicon wafer. Preferably, the electrodynamic actuator is formed at least largely of copper, preferably of at least 80%, particularly preferably at least 90% copper, in particular low-dissipation copper. Preferably, the electrodynamic actuator is designed as a copper coil, in particular a drive coil. The microelectronic device can comprise conducting tracks, in particular copper conducting tracks, in particular ones that are different from the electrodynamic actuator, and/or vias, in particular copper vias. Preferably, the at least one electrodynamic actuator is provided to drive the quasi-static axis. Preferably, the piezoelectric actuator is provided to drive the resonant axis. “Provided” should in particular be understood to mean specially programmed, configured, and/or equipped. An object being provided for a particular function should in particular be understood to mean that the object fulfills and/or performs this particular function in at least one application state and/or operating state.

In accordance with an example embodiment of the present invention, preferably, in the at least one method step, the at least one electrodynamic actuator is introduced into, in particular applied to, recesses in a CMOS substructure on the carrier substrate at least in part. Preferably, in at least one annealing step, which is in particular different from the at least one method step and the at least one further method step, the at least one electrodynamic actuator is annealed on the carrier substrate, in particular on the CMOS substructure, at at least 400° C., preferably at at least 450° C., particularly preferably at at least 500° C., and most particularly preferably at at least 530° C. Preferably, in the at least one further method step, at least the at least one piezoelectric actuator, which is made of a piezoelectric ceramic, in particular having a molecular formula AₓB_{y}O₃, and can in particular be doped with different materials, for example with lanthanum and/or niobium, is applied to the at least one carrier substrate, to which in particular at least the at least one electrodynamic actuator is applied. Preferably, in the at least one further method step, at least the piezoelectric actuator is applied to the at least one carrier substrate, to which in particular at least the at least one electrodynamic actuator is applied, at a temperature of at least 450° C., in particular at least 480° C. Preferably, in the at least one further method step, at least one piezoelectric actuator is deposited on the at least one carrier substrate.

Owing to the method according to the present invention, in particular owing to a particular order of method steps in the method according to the present invention, an advantageously cost-effective and highly functional microelectronic unit can be provided which in particular combines intrinsic conductivity properties of the electrodynamic actuator with advantageous piezoelectric properties of the piezoelectric actuator.

Furthermore, in accordance with an example embodiment of the present invention, it is provided that the at least one piezoelectric actuator is made of a PZT material or a KNN material. Preferably, in the at least one further method step, the at least one piezoelectric actuator, which is made of a KNN material, in particular a potassium sodium niobate, and/or a PZT material, in particular a lead zirconate titanate, is applied to the at least one carrier substrate, to which in particular the at least one electrodynamic actuator is applied, preferably at least in part as a copper coil and in particular additionally in part as a conducting track and/or as a via. An advantageously large dynamic actuator range of the piezoelectric actuator can be obtained, in particular due to the intrinsic piezoelectric properties of a KNN material and/or a PZT material. In particular, in a dynamic mode of the piezoelectric actuator, in particular when in resonance, an advantageously large deflection angle can be obtained together with advantageously low energy consumption.

Furthermore, in accordance with an example embodiment of the present invention, it is provided that the at least one further method step is carried out after the at least one method step. Preferably, the at least one further method step is carried out after the at least one annealing step, in particular after at least two annealing steps. Preferably, the at least one annealing step is carried out between the at least one method step and the at least one further method step. An advantageously cost-effective microelectronic device can be formed, in particular because there is advantageously no need to protect a copper region in a factory from contamination when applying the electrodynamic actuator.

Furthermore, in accordance with an example embodiment of the present invention, it is provided that, in at least one method step, a CMOS substructure, in particular the one that has already been mentioned, is applied to the at least one carrier substrate. Preferably, in at least one method step, a CMOS substructure made of a borosilicate glass and a silicon nitride is applied to the at least one carrier substrate. Preferably, in at least one method step, a borosilicate glass layer is applied to the at least one carrier substrate, in particular as part of the CMOS substructure. Preferably, in at least one method step, a silicon nitride layer is applied to the at least one borosilicate glass layer, in particular as part of the CMOS substructure. Preferably, in at least one method step, the silicon nitride layer is applied to the at least one borosilicate glass layer using plasma-assisted chemical vapor deposition. Preferably, in at least one method step, the borosilicate glass layer is provided with W plugs. Preferably, in at least one method step, the at least one carrier substrate is provided with diffusions, in particular in the vicinity of W plugs in the borosilicate glass layer. Preferably, in at least one method step, a silicon oxide layer is applied to the at least one silicon nitride layer, in particular as part of the CMOS substructure, in particular using plasma-assisted chemical vapor deposition. Preferably, in at least one method step, a further silicon nitride layer is applied to the at least one silicon oxide layer, in particular as part of the CMOS substructure, preferably using plasma-assisted chemical vapor deposition. Preferably, in at least one method step, the recesses are made, in particular etched, in the CMOS substructure on the carrier substrate, in particular to receive the electrodynamic actuator and/or conducting tracks and/or vias. Preferably, in at least one method step before the at least one annealing step, the at least one electrodynamic actuator is applied to the carrier substrate, in particular and/or introduced into recesses in the CMOS substructure on the carrier substrate, using plating technology, in particular electroplating. Preferably, in the at least one processing step, at least one piezoelectric actuator is applied to the at least one carrier substrate comprising a CMOS substructure and at least one, in particular low-resistance, electrodynamic actuator. A piezoelectric actuator and an electrodynamic actuator can advantageously be integrated on a carrier substrate comprising a CMOS substructure. In particular, a MEMS resonator having a complete CMOS substructure can advantageously be integrated, in particular for subsequent hermetic encapsulation.

Furthermore, in accordance with an example embodiment of the present invention, it is provided that, in at least one method step, at least one piezoelectric stack, which is formed in part by the at least one piezoelectric actuator, is applied to the CMOS substructure on the at least one carrier substrate. Preferably, in at least one method step, at least one piezoelectric stack 18, in particular a pyramidal piezoelectric stack, in particular the at least one piezoelectric actuator, is arranged on the at least one carrier substrate, in particular on the CMOS substructure. Preferably, in at least one method step, an adhesion layer of the piezoelectric stack is applied to the CMOS substructure, in particular directly to the further silicon nitride layer. Preferably, in at least one method step, an electrode layer, in particular a platinum layer, of the piezoelectric stack is applied to the at least one adhesion layer. Preferably, in at least one method step, a seed layer of the piezoelectric stack is applied to the electrode layer. Preferably, in at least one method step, the piezoelectric actuator, in particular the piezoelectric crystal, of the piezoelectric stack is applied to the seed layer. Preferably, in at least one method step, a further electrode layer, in particular a platinum layer, of the piezoelectric stack is applied to the at least one piezoelectric actuator. Preferably, in at least one method step, the piezoelectric stack is passivated by a barrier layer of the piezoelectric stack and an additional silicon nitride layer of the piezoelectric stack, in particular on a side of the piezoelectric stack facing away from the carrier element. Preferably, in at least one method step, the electrode layer and/or the further electrode layer is/are designed to be electrically contactable via electrical contacts, in particular by the at least one barrier layer of the piezoelectric stack, in particular through etched recesses therein, and/or the at least one silicon nitride layer of the piezoelectric stack. Preferably, in at least one method step, the at least one electrodynamic actuator is designed to be electrically contactable via an electrical contact.

Preferably, in accordance with an example embodiment of the present invention, in at least one method step, a further electrical contact and an additional electrical contact are arranged to be spaced apart from one another, in particular to contact different sides of the piezoelectric actuator.

Furthermore, in accordance with an example embodiment of the present invention, it is provided that, in at least one method step, the at least one piezoelectric stack is structured. Preferably, in at least one method step, at least one layer of the at least one piezoelectric stack is structured. Preferably, in at least one method step, the at least one piezoelectric actuator is structured as part of the piezoelectric stack. Preferably, in at least one method step, the at least one barrier layer and/or the at least one silicon nitride layer of the piezoelectric stack are structured. Preferably, in at least one method step, at least one recess is made, in particular etched, in the at least one barrier layer and/or the at least one silicon nitride layer of the piezoelectric stack. In particular, the at least one recess is provided in the at least one barrier layer and/or the at least one silicon nitride layer for receiving at least one electrical contact. Advantageously cost-effective electrical contactability of the piezoelectric actuator, in particular the electrodynamic actuator, can be obtained.

Furthermore, in accordance with an example embodiment of the present invention, it is provided that, in the at least one method step, the at least one electrodynamic actuator is applied to, in particular deposited on, the carrier substrate in a damascene process, preferably a copper damascene process. Preferably, in the method step, the at least one electrodynamic actuator is, at least in part, introduced into, in particular applied to, recesses in a CMOS substructure on the carrier substrate in a copper damascene process. Preferably, in the at least one method step, in particular before the at least one annealing step, the at least one electrodynamic actuator is applied to the carrier substrate, in particular and/or introduced into recesses in the carrier substrate, using plating technology, in particular electroplating, preferably by way of a damascene process. Preferably, in at least one method step, in particular before the at least one annealing step, at least one recess for the at least one electrodynamic actuator is etched in the carrier substrate and/or a layer positioned on the carrier substrate, preferably in the CMOS substructure. Preferably, in at least one method step, in particular before the at least one annealing step, a copper seed layer is sputtered onto the at least one carrier substrate, preferably into the at least one recess in the CMOS substructure. An advantageously large-scale, in particular cost-effective, formation process for the at least one electrodynamic actuator can be obtained.

Furthermore, in accordance with an example embodiment of the present invention, it is provided that, in at least one method step, the at least one carrier substrate is trenched. Preferably, in at least one method step, the at least one carrier substrate is trenched at least in part from a side facing the CMOS substructure. In particular, in at least one method step, at least one recess is made, in particular trenched, in the at least one carrier substrate, for example by wet etching and/or dry etching and/or physical removal of material from the carrier substrate. In particular, in at least one method step, the at least one carrier substrate is divided into movable parts, in particular MEMS structures, by trenches. In particular, in at least one method step, the at least one carrier substrate can be completely trenched, in particular perpendicularly to the largest substrate surface, and can in particular be through-trenched. An advantageously movable microelectronic device, in particular a MEMS chip device, can be obtained.

Furthermore, in accordance with an example embodiment of the present invention, there is provided a microelectronic device, in particular a MEMS chip device, which is produced by a method according to the present invention.

Furthermore, it is proposed that the microelectronic device comprises at least one carrier substrate, on which at least one piezoelectric actuator is arranged, which is in particular made of a piezoelectric perovskite material, and wherein at least one electrodynamic actuator made of a metal conductor formed at least largely of copper is arranged on the carrier substrate.

The method according to the present invention and/or the microelectronic device according to the present invention are not intended to be limited to the above-described application and specific embodiment in this case. In particular, to implement a mode of operation described herein, the method according to the present invention and/or the microelectronic device according to the present invention can have a number of individual elements, components, and units, as well as method steps, which is different from a number mentioned herein. In addition, for the value ranges stated in this disclosure, values within the stated limits should also be taken to be disclosed and applicable in any manner.

### BRIEF DESCRIPTION OF THE DRAWINGS

Further advantages will become clear from the following description of the figures. An exemplary embodiment of the present invention is shown in the figures. The figures and the description contain many features in combination. A person skilled in the art will also expediently consider the features in isolation and combine them into further, useful combinations, in view of the disclosure herein.

FIG. 1 is a schematic view of a microelectronic device according to an example embodiment of the present invention.

FIG. 2 is a schematic view of the microelectronic device according to an example embodiment of the present invention.

FIG. 3 is a schematic representation of a method according to an example embodiment of the present invention.

### DETAILED DESCRIPTION OF EXAMPLE EMBODIMENTS

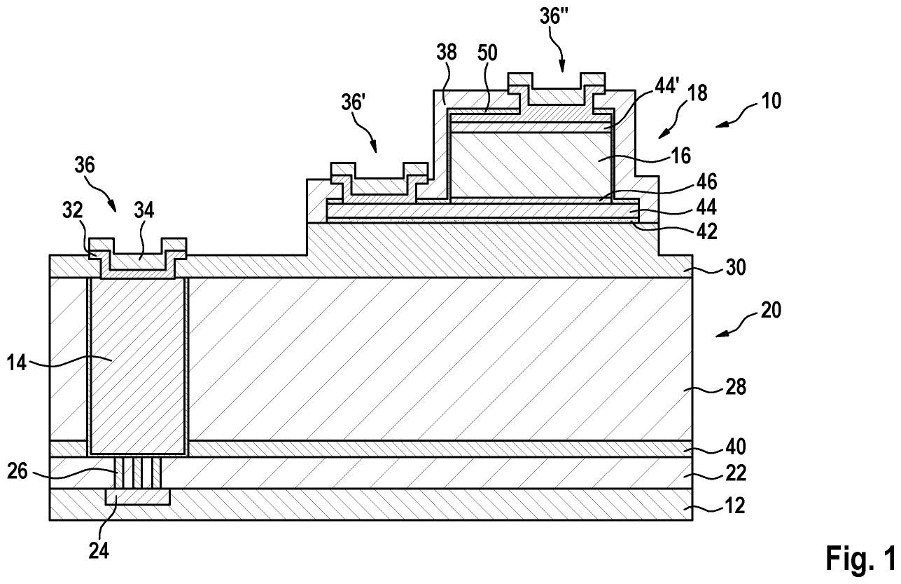

FIG. 1 shows a microelectronic device 10, in particular a MEMS chip device. The microelectronic device 10 comprises a carrier substrate 12. A piezoelectric actuator 16 is arranged on the carrier substrate 12. The piezoelectric actuator 16 is made of a piezoelectric perovskite material. An electrodynamic actuator 14 is arranged on the carrier substrate 12. The electrodynamic actuator 14 is made of a metal conductor formed at least largely of copper.

Diffusions 24, in particular n-dopant and/or p-dopant atoms, are arranged in the carrier substrate 12. The microelectronic device 10 comprises the electrodynamic actuator 14. The microelectronic device 10 comprises the piezoelectric actuator 16. The microelectronic device 10 comprises a CMOS substructure 20.

The CMOS substructure 20 comprises four layers by way of example. The CMOS substructure 20 can comprise a borosilicate glass layer 22 which is arranged directly on the carrier substrate 12 and in which one or more W plugs 26 are arranged.

The CMOS substructure 20 comprises a silicon nitride layer 40 arranged directly on the borosilicate glass layer 22. The CMOS substructure 20 comprises a silicon oxide layer 28 which is arranged directly on the silicon nitride layer 40 and in particular has a thickness that is greater than, in particular at least three times greater than, the silicon nitride layer 40 and/or the borosilicate glass layer 22. The CMOS substructure 20 comprises a further silicon nitride layer 30 arranged directly on the silicon oxide layer 28. The further silicon nitride layer 30 in particular passivates the electrodynamic actuator 14 on a side facing away from the carrier substrate 12.

The electrodynamic actuator 14 is integrated in the CMOS substructure 20, in particular is arranged in the silicon nitride layer 40 and the silicon oxide layer 28. The electrodynamic actuator 14 is connected to the diffusions 24 in the carrier substrate 12 via one or more W plugs 26. The electrodynamic actuator 14 can be electrically connected, in particular by the further silicon nitride layer 30, via an electrical contact 36 in the further silicon nitride layer 30. The electrical contact 36, 36′, 36″ comprises an aluminum and/or copper layer 34 and a barrier layer 32, which is in particular arranged between the electrodynamic actuator 14 and the aluminum and/or copper layer 34.

A piezoelectric stack 18, in particular the piezoelectric actuator 16, is arranged on the carrier substrate 12, in particular on the CMOS substructure 20. The piezoelectric actuator 16 is in particular made of a perovskite ceramic, such as a KNN or PZT ceramic. The piezoelectric actuator 16 is made of a PZT material or a KNN material. The piezoelectric stack 18 comprises an adhesion layer 42, in particular a TaN layer, a TiN layer, or a titanium oxide layer, which is in particular arranged directly on the further silicon nitride layer 30. The piezoelectric stack 18 comprises an electrode layer 44, in particular a platinum layer, which is in particular arranged directly on the adhesion layer 42. The piezoelectric stack 18 comprises a seed layer 46, in particular an LNO layer, in particular an LaNiO3 layer, or a PbO layer, which is in particular arranged directly on the electrode layer 44. The electrode layer 44, 44′ is in particular made of platinum. The piezoelectric stack 18 is formed in part by the piezoelectric actuator 16, which is in particular arranged directly on the seed layer 46. The piezoelectric stack 18 comprises a further electrode layer 44, which is in particular arranged directly on the piezoelectric actuator 16. The electrode layer 44 can be electrically contacted via a further electrical contact 36′. The further electrode layer 44 can be electrically contacted via an additional electrical contact 36″. The further electrical contact 36′ and the additional electrical contact 36″ are arranged to be spaced apart from one another, in particular to contact different sides of the piezoelectric actuator 16. The piezoelectric stack 18 is passivated by a barrier layer 50, in particular a TaN layer, a TiN layer, or a titanium oxide layer, and an additional silicon nitride layer 38, in particular on a side facing away from the carrier element. The piezoelectric actuator 16 is formed as a piezoelectric thin film. The piezoelectric stack 18 can comprise a further barrier layer 50, in particular a TaN layer, a TiN layer, or a titanium oxide layer, in particular between the piezoelectric actuator 16 and the further electrode layer 44′.

The microelectronic device 10 can be designed as a MEMS scanner or a MEMS gyroscope.

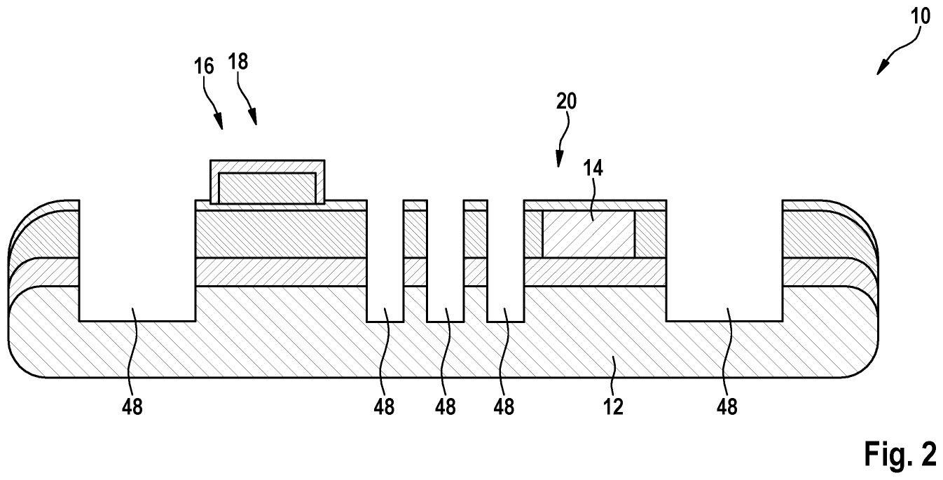

FIG. 2 shows the microelectronic device 10, in particular in a trenched state, comprising a structured CMOS substructure 20, with the carrier substrate 12 being trenched in particular. The carrier substrate 12 preferably comprises grooves, in particular trenches 48. The trenches 48 extend through the CMOS substructure 20 on the carrier substrate 12.

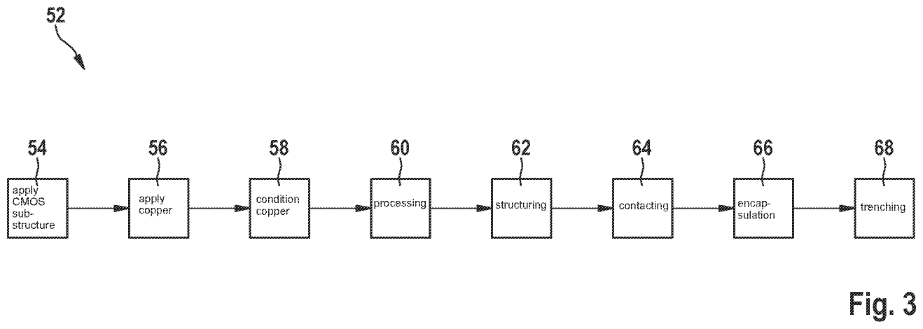

FIG. 3 shows a method 52 for producing a microelectronic device 10, in particular a MEMS chip device. The microelectronic device 10, in particular the MEMS chip device, is in particular produced using the method 52 shown in FIG. 3 for producing a microelectronic device 10.

In at least one method step, in particular a CMOS step 54, the CMOS substructure 20 is applied to, in particular deposited on, the carrier substrate 12. In the CMOS step 54, in particular metal regions and/or n-doped and/or p-doped troughs, in particular the diffusions 24, are formed in the carrier substrate 12. In the CMOS step 54, conducting tracks, piezoresistors, and/or transistors can in particular be formed.

In at least one method step, in particular a copper-applying step 56, the electrodynamic actuator 14 made of a metal conductor formed at least largely of copper is applied to the carrier substrate 12. In at least one method step, in particular the copper-applying step 56, the electrodynamic actuator 14 is applied to the carrier substrate 12 in a damascene process, in particular by plating technology. In particular, the copper-applying step 56 is carried out after the CMOS step 54. In particular, recesses, in particular grooves, are etched in the CMOS substructure 20 in the copper-applying step 56. In particular, the recesses are lined with barrier layers and seed layers, such as Ta layers and/or TaN layers, in the copper-applying step 56. In particular, in the copper-applying step 56, the lined recesses are filled with copper using plating technology, in particular in a copper damascene process, in particular to form the electrodynamic actuator 14. In particular, in the copper-applying step 56, the electrodynamic actuator 14 is planarized to a height of the CMOS substructure 20.

In at least one method step, in particular a copper-conditioning step 58, the electrodynamic actuator 14 is processed on the carrier substrate 12, in particular annealed at over 400° C., preferably at over 500° C., particularly preferably at at least 530° C. In the copper-conditioning step 58, the electrodynamic actuator 14 is passivated by an insulator, in particular by an insulator layer, for example the further silicon nitride layer 30. The copper-conditioning step 58 is in particular carried out after the copper-applying step 56.

In at least one further method step, in particular a processing step 60, the piezoelectric actuator 16 is applied to, in particular deposited on, the carrier substrate 12. In the at least one further method step, in particular the processing step 60, the piezoelectric stack 18, which is formed in part by the piezoelectric actuator 16, is applied to, in particular deposited on, the CMOS substructure 20 on the at least one carrier substrate 12. In the at least one further method step, in particular the processing step 60, the piezoelectric stack 18 is passivated by an insulator.

The at least one further method step, in particular the processing step 60, is in particular carried out after the at least one method step, in particular the at least one copper-applying step 56 and/or the copper-conditioning step 58.

In at least one method step, in particular a structuring step 62, the piezoelectric stack 18 is structured, in particular provided with recesses. In particular, in the structuring step 62, recesses are made, preferably etched, in the additional silicon nitride layer 38 and/or in the barrier layer 50. In particular, in the structuring step 62, at least one recess can be made, preferably etched, in the further silicon nitride layer 30. In particular, etched areas made in the structuring step 62 can cover a greater area than trenches 48 in the carrier substrate 12. The structuring step 62 is in particular carried out after the processing step 60. In a method step, in particular in the structuring step 62, the piezoelectric stack 18 can be provided with a pyramidal structure, in particular by removing material from the individual layers.

In at least one method step, in particular a contacting step 64, the at least one piezoelectric stack 18 and/or the at least one electrodynamic actuator 14 is electrically contacted, in particular wired, by electrical contacts 36, 36′, 36″. In the contacting step 64, the piezoelectric stack 18 can for example be electrically connected to the CMOS substructure 20. The contacting step 64 is in particular carried out after the structuring step 62.

In at least one method step, in particular an encapsulation step 66, the piezoelectric actuator 16 together with the electrodynamic actuator 14 can be hermetically encapsulated on the at least one carrier substrate 12, in particular at at least 400° C., preferably at at least 430° C. The encapsulation step 66 is in particular carried out after the contacting step 64.

In at least one method step, in particular a trenching step 68, the at least one carrier substrate 12 can be trenched, in particular completely through-trenched, in particular to produce movable MEMS structures. In particular, in the trenching step 68, the carrier substrate 12 can be partially trenched or completely trenched from two sides, in particular both sides, in particular to form movable MEMS structures. In particular, the trenching step 68 can be carried out before and/or after the encapsulation step 66.

In an optional method step, in particular before the trenching step 68, the insulator layer, in particular the further silicon nitride layer 30, and/or the silicon oxide layer 28 and/or another oxide layer of the CMOS substructure 20, can be etched, in particular locally.

In particular, the processing step 60 can be carried out before the copper-applying step 56 and the copper-conditioning step 58. In this case, the piezoelectric stack 18 is applied to the CMOS substructure 20 and is then passivated by the other oxide layer. In one method step, the other oxide layer is planarized. In one method step, at least one recess for the at least one electrodynamic actuator 14 is made in the other oxide layer. The method 52 can then be performed from the copper-applying step 56 onward, in particular without the processing step 60.

1-10. (canceled)

11. A method for producing a microelectronic MEMS chip device including at least one carrier substrate, the method comprising the following steps:
applying at least one electrodynamic actuator made of a metal conductor formed at least largely of copper to the carrier substrate; and
applying at least one piezoelectric actuator to the carrier substrate.

12. The method as recited in claim 11, wherein the at least one piezoelectric actuator is made of a PZT material or a KNN material.

13. The method as recited in claim 11, wherein the piezoelectric actuator is applied to the carrier substrate after the at least one electrodynamic actuator is applied to the carrier substrate.

14. The method as recited in claim 11, further comprising:
applying a CMOS substructure to the at least one carrier substrate.

15. The method as recited in claim 14, wherein at least one piezoelectric stack, which is formed in part by the at least one piezoelectric actuator, is applied to the CMOS substructure on the at least one carrier substrate.

16. The method as recited in claim 15, wherein the at least one piezoelectric stack is structured.

17. The method as recited in claim 15, wherein the at least one electrodynamic actuator is applied to the carrier substrate in a damascene process.

18. The method as recited in claim 15, further comprising:
trenching the at least one carrier substrate is trenched.

19. A microelectronic device, the micromechanical device comprising:
a carrier substrate on which at least one electrodynamic actuator made of a metal conductor formed at least largely of copper is applied, and one which at least one piezoelectric actuator is applied.

20. The microelectronic device, comprising:
at least one carrier substrate;
at least one piezoelectric actuator, made of a PZT material or a KNN material, arranged on the carrier substrate; and
at least one electrodynamic actuator, made of a metal conductor formed at least largely of copper, arranged on the carrier substrate.
